(19) United States
(12) Patent Application Publication
(10) Pub. No.: US 2007/0170488 A1
(43) Pub. Date: Jul. 26, 2007

(54) Capacitor of semiconductor device and method for fabricating the same

(75) Inventors: Mi-Young Ryu, Seoul (KR); Hee-Il Chae, Seoul (KR)

Correspondence Address: HARNESS, DICKEY & PIERCE, P.L.C., P.O. BOX 8910, RESTON, VA, 20195, US

(73) Assignee: Samsung Electronics Co. Ltd.

(21) Appl. No.: 11/655,944

(22) Filed: Jan. 22, 2007

(30) Foreign Application Priority Data
Jan. 23, 2006 (KR) 10-2006-0006877

(51) Int. Cl. H01L 27/108; H01L 21/20

(52) U.S. Cl. 257/308; 438/399; 257/E27.086

(57) ABSTRACT

A capacitor of a semiconductor device and a method for fabricating the same may be provided. The method may include forming an interlayer insulation layer, an etch stop layer, and/or a sacrificial insulation layer on a semiconductor substrate, patterning the interlayer insulation layer, the etch stop layer, and/or the sacrificial insulation layer to form a contact hole exposing a desired or predetermined region of the semiconductor substrate, filling the contact hole to form a contact plug, removing the sacrificial insulation layer to expose an upper portion of the contact plug, and/or forming a dielectric layer and/or a top electrode on the exposed upper portion of the contact plug.

### PRIORITY STATEMENT

This application claims the benefit of priority to Korean Patent Application No. 10-2006-0006877, filed on Jan. 23, 2006, in the Korean Intellectual Property Office, the entire contents of which is incorporated herein in its entirety by reference.

### BACKGROUND

1. Field

Example Embodiments relate to a semiconductor device, and for example, to a capacitor of a semiconductor device and a method for fabricating the same.

2. Description of Related Art

Because semiconductor devices have been highly integrated, a region that unit devices may occupy on a semiconductor wafer may become more reduced. Accordingly, a region that a capacitor may occupy may also become more reduced. The capacitor may be widely used in memory devices such as Dynamic Random Access Memory (DRAM) and/or Static RAM (SRAM). The capacitor may include respectively opposite conductive layers and/or a dielectric layer between the conductive layers. The capacitor may require a desired or predetermined level of capacitance.

There have been many efforts to improve capacitance of the capacitor. A surface region of respectively opposite conductive layers may usually be increased to improve capacitance of the capacitor.

A three-dimensional capacitor may be used to increase the surface region of the capacitor. A representative three-dimensional capacitor may be a stack capacitor. Examples of the stack capacitor may be a double-stacked capacitor, a fin-stacked capacitor, a cylindrical capacitor, and/or a box-structure capacitor.

The inner surface and/or the outer surface of the cylindrical capacitor may be effective regions of the capacitor. The cylindrical capacitor may be one ideal form.

FIG. 1 is a cross-sectional view of a capacitor of a semiconductor device according to the conventional art.

Referring to FIG. 1, a device isolation layer 12 may be formed on a semiconductor substrate 10 using a conventional device isolation process.

A gate oxide layer 14, a gate electrode 16, and/or impurity regions (source and drain regions 18s and 18d) may be formed on the semiconductor substrate 10 by using a conventional Metal-Oxide Semiconductor (MOS) transistor manufacturing process.

A first interlayer insulation layer 20 may be formed on the semiconductor substrate 10 having the MOS transistor. The first interlayer insulation layer 20 may include contact holes 21 that may be formed to expose the impurity regions 18s and 18d. Contact plugs 22 may be formed to fill the contact holes 21.

An etch stop layer 24 and/or a second interlayer insulation layer 26 having an opening may be formed on the first interlayer insulation layer 20 having the contact plugs 22. The opening may expose a desired or predetermined region of the first interlayer insulation layer 20 having the contact plugs 22 connected to the drain regions 18d.

A bottom electrode 30 may be formed according to an inner profile of the opening. According to a profile of the second interlayer insulation layer 26 having the bottom electrode 30, a dielectric layer 35 and/or a top electrode 40 may be formed by depositing and/or patterning a dielectric material and/or a top conductive layer.

A third interlayer insulation layer 50 may be formed on the second interlayer insulation layer 26 having the top electrode 40. The third interlayer insulation layer 50 may include a bit-line contact hole 51b exposing the contact plug 22 connected to the source region 18s, and/or a metal-line contact hole 51m exposing a desired or predetermined region of the top electrode 40. A bit-line contact plug 52b and/or a metal-line contact plug 52m may be formed to fill the bit-line contact hole 51b and/or the metal-line contact hole 51m, respectively.

When manufacturing an inner cylinder capacitor of the semiconductor device having the above Capacitor Under Bit line (CUB), manufacturing cost may increase and manufacturing processes may become more complex due to use of a mask twice for forming a bit line contact plug, and/or a sacrificial material layer for separating a bottom electrode.

Because the semiconductor device may become highly integrated, a design rule may be reduced. Accordingly, it may be difficult to form an effective coverage of the inner cylinder capacitor. Accordingly, voids may occur in the capacitor such that it may be difficult for the semiconductor device to perform stable operations.

### SUMMARY

Example Embodiments may provide a capacitor of a semiconductor device simplifying processes during manufacturing a capacitor of a semiconductor device, and/or achieving stability of a capacitance of a capacitor and/or semiconductor device, and/or a method for fabricating the same.

According to an example embodiment, a method for fabricating a capacitor of a semiconductor device may include forming an interlayer insulation layer, an etch stop layer, and/or a sacrificial insulation layer on a semiconductor substrate, patterning the interlayer insulation layer, the etch stop layer, and/or the sacrificial insulation layer to form a contact hole exposing a desired or predetermined region of the semiconductor substrate, filling the contact hole to form a contact plug, removing the sacrificial insulation layer to expose an upper portion of the contact plug, and/or forming a dielectric layer and/or a top electrode on the exposed upper portion of the contact plug.

According to an example embodiment, the interlayer insulation layer and/or the sacrificial insulation layer may be silicon oxide. The etch stop layer may be one of a silicon oxide nitride layer and a silicon nitride layer.

According to an example embodiment, the contact plug may be tungsten. The exposed upper portion of the contact plug may be used as a bottom electrode.

According to an example embodiment, the forming of an additional bottom electrode may include forming a bottom conductive layer on the exposed contact plug, and the additional bottom electrode may be formed on the exposed upper portion of the contact plug by patterning the bottom conductive layer. The bottom conductive layer may be titanium nitride. The bottom conductive layer may be patterned by using an entire surface etching process.

According to an example embodiment, a capacitor of a semiconductor device may include a semiconductor substrate, an interlayer insulation layer and/or an etch stop layer covering an entire surface of the semiconductor substrate, a contact plug protruding from the etch stop layer and being connected to a desired or predetermined region of the semiconductor substrate, and/or a dielectric layer and/or a top electrode arranged along a profile of the protruding portion of the contact plug and/or the etch stop layer.

According to an example embodiment, a gate electrode may be on the semiconductor substrate, and the interlayer insulation layer and the etch stop layer covering the entire surface of the semiconductor substrate may cover the gate electrode.

According to an example embodiment, the interlayer insulation layer may be a silicon oxide layer. The etch stop layer may be one of a silicon oxide nitride layer and a silicon nitride layer.

According to an example embodiment, the contact plug may be tungsten. The protruding portion of the contact plug may be used as a bottom electrode.

According to an example embodiment, the capacitor may further include an additional bottom electrode on the protruding portion of the contact plug. The additional bottom electrode may be a titanium nitride layer.

According to an example embodiment, the dielectric layer may be one of a double layer having an aluminum oxide layer and a hafnium oxide layer stacked, and a tantalum oxide layer. The double layer may have an aluminum oxide layer and a hafnium oxide layer sequentially stacked. The top electrode may be a titanium nitride layer.

### BRIEF DESCRIPTION OF THE DRAWINGS

The above and/or other aspects and advantages will become more apparent and more readily appreciated from the following detailed description of example embodiments taken in conjunction with the accompanying drawings of which:

FIG. 1 is a cross-sectional view of a capacitor of a semiconductor device according to the conventional art;

FIGS. 2A to 2G are cross-sectional views illustrating a method for fabricating a capacitor of a semiconductor device according to an example embodiment; and

FIGS. 3A to 3G are cross-sectional views illustrating a method for fabricating a capacitor of a semiconductor device according to another example embodiment.

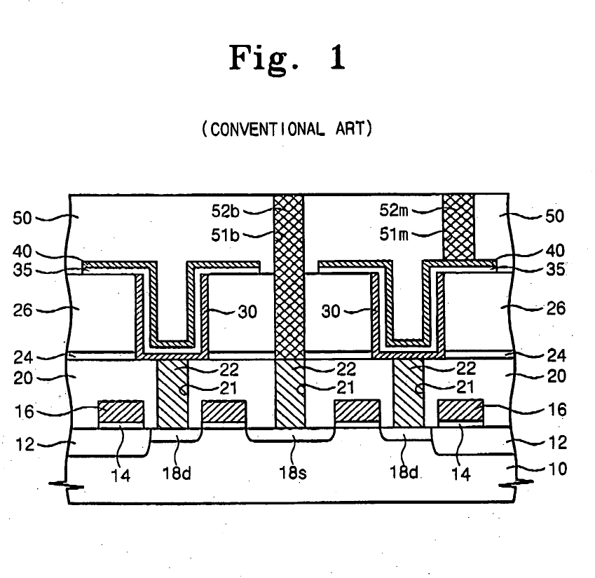

### DETAILED DESCRIPTION OF EXAMPLE EMBODIMENTS

Example embodiments will now be described more fully hereinafter with reference to the accompanying drawings. Embodiments may, however, be in many different forms and should not be construed as being limited to the example embodiments set forth herein. Rather, these example embodiments are provided so that this disclosure will be thorough and complete, and will fully convey the scope to those skilled in the art. In the drawings, the thicknesses of layers and regions may be exaggerated for clarity.

It will be understood that when a component is referred to as being “on,” “connected to” or “coupled to” another component, it can be directly on, connected to or coupled to the other component or intervening components may be present. In contrast, when a component is referred to as being “directly on,” “directly connected to” or “directly coupled to” another component, there are no intervening components present. As used herein, the term “and/or” includes any and all combinations of one or more of the associated listed items.

It will be understood that, although the terms first, second, third, etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, a first element, component, region, layer or section discussed below could be termed a second element, component, region, layer or section without departing from the teachings of the example embodiments.

Spatially relative terms, such as “beneath,” “below,” “lower,” “above,” “upper” and the like, may be used herein for ease of description to describe one component or feature's relationship to another component(s) or feature(s) as illustrated in the drawings. It will be understood that the spatially relative terms are intended to encompass different orientations of the device in use or operation in addition to the orientation depicted in the figures.

The terminology used herein is for the purpose of describing particular example embodiments only and is not intended to be limiting. As used herein, the singular forms “a,” “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, and/or components.

Unless otherwise defined, all terms (including technical and scientific terms) used herein have the same meaning as commonly understood by one of ordinary skill in the art to which example embodiments belong. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

Reference will now be made to example embodiments, which are illustrated in the accompanying drawings, wherein like reference numerals refer to the like components throughout.

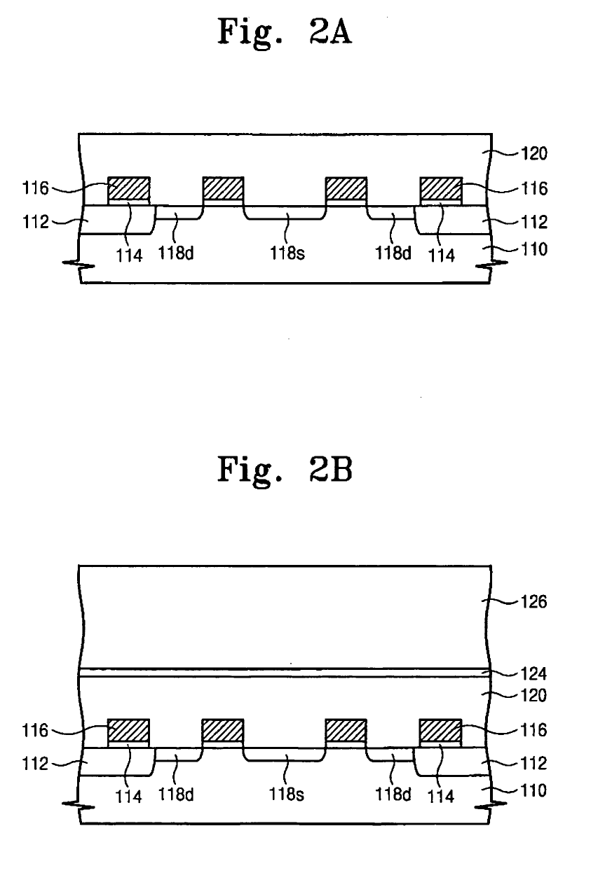

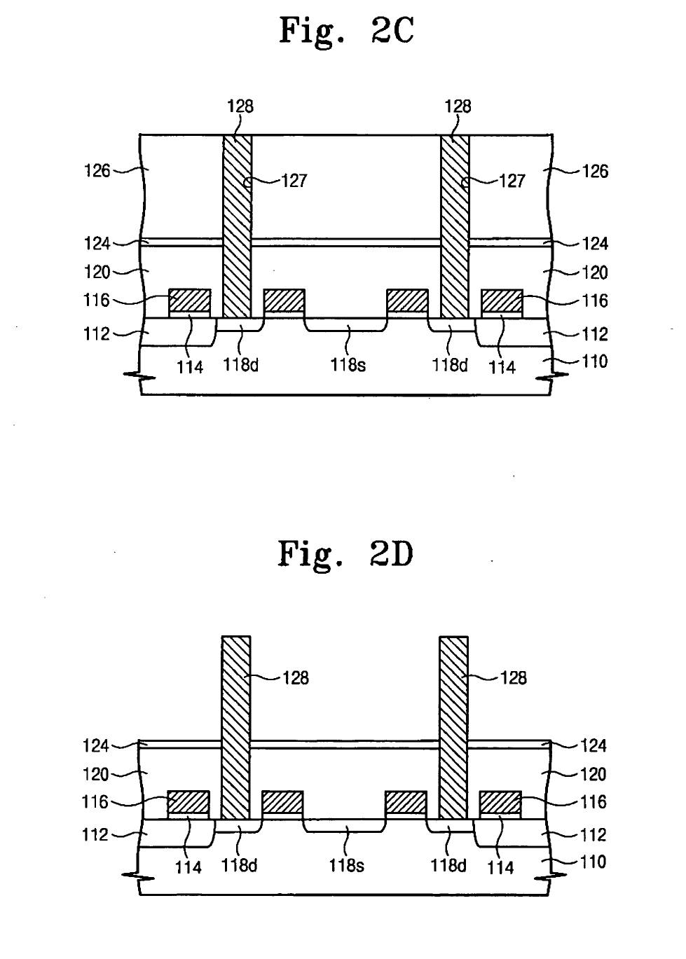

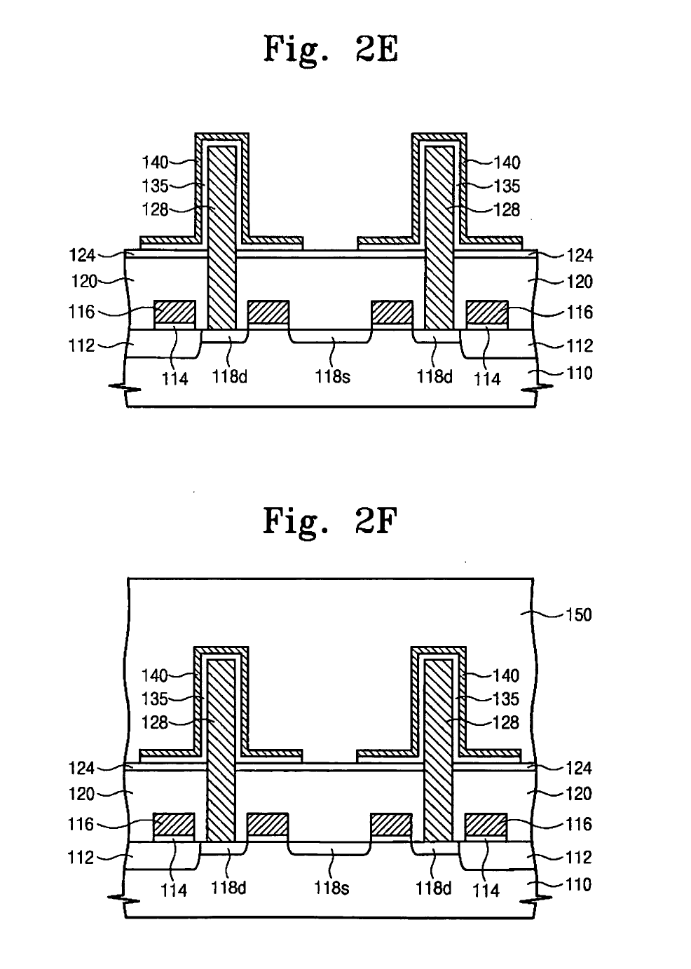

FIGS. 2A to 2G are cross-sectional views illustrating a method for fabricating a capacitor of a semiconductor device according to an example embodiment.

Referring to FIG. 2A, a device isolation layer 112 may be formed on a semiconductor substrate 110 by using a conventional device isolation process.

A gate oxide layer 114, a gate electrode 116, and/or impurity regions (source/drain regions 118s/118d) may be formed on the semiconductor substrate 110 by using a conventional MOS transistor manufacturing process. The gate oxide layer 114 may be a thermal oxide layer. The gate electrode 116 may be formed of polysilicon. The impurity regions 118s and 118d may be formed by using an ion implantation process.

An interlayer insulation layer 120 may be formed to cover an entire surface of the semiconductor substrate 110 having the MOS transistor. The interlayer insulation layer 120 may be a silicon oxide layer deposited by using a Chemical Vapor Deposition (CVD) process. The interlayer insulation layer 120 may be a TetraEthly OrthoSilicate (TEOS) layer deposited by using a Plasma Enhanced CVD (PE-CVD) process. The interlayer insulation layer 120 may be formed of a thickness of 6,000 to 7,000 Å.

Referring to FIG. 2B, an etch stop layer 124 and/or a sacrificial insulation layer 126 may be formed on the interlayer insulation layer 120. For example an etch stop layer 124 and a sacrificial oxide layer 126 may be sequentially formed on the interlayer insulation layer 120. The etch stop layer 124 may be a silicon nitride layer or a silicon oxide nitride layer, which may be deposited by using a PE-CVD process. The etch stop layer 124 may be formed of a thickness of about 400 Å. The sacrificial insulation layer 126 may be a silicon oxide layer deposited by using a CVD process. The sacrificial insulation layer 126 may be a TEOS layer deposited by using a PE-CVD process.

Referring to FIG. 2C, the sacrificial insulation layer 126, the etch stop layer 124, and/or the interlayer insulation layer 120 may be etched by using photolithography to form a contact hole 127 exposing a desired or predetermined region of the drain region 118d. A contact plug 128 may be formed to fill the contact hole 127. The contact plug 128 may be formed of tungsten by using a Pulsed Nucleation Layer (PNL) formation process.

Before the forming of the contact plug 128, a barrier metal layer (not shown) may be formed to reduce diffusion at interface between the contact plug 128 and the interlayer insulation layer 120, which may contact each other. The barrier metal layer may be a double layer having stacked titanium and titanium nitride. For example, the barrier metal layer may be a double layer having sequentially-stacked titanium and titanium nitride.

Referring to FIG. 2D, the sacrificial insulation layer 126 may be removed to expose a portion of the contact plug 128, which may be above the etch stop layer 124. The contact plug 128 may protrude from the etch stop layer 124. The contact plug 128 protruding from the etch stop layer 124 may be used as a bottom electrode of a capacitor.

A bottom conductive layer may be additionally deposited on the protruding portion of the contact plug 128 to form a bottom electrode (not shown) by patterning dielectric material, which may be deposited later, and/or a top conductive layer simultaneously.

Referring to FIG. 2E, along a profile of the etch stop layer 124 including the contact plug 128 that may protrude from the etch stop layer 124, the dielectric material and/or the top conductive layer may be deposited and/or patterned to form a dielectric layer 135 and/or a top electrode 140. Accordingly, the capacitor may include the bottom electrode by using the protruding portion of the contact plug 128, the dielectric layer 135, and/or the top electrode 140.

The dielectric material may be formed of a double layer having an aluminum oxide layer and a hafnium oxide layer stacked, or a single layer having a tantalum oxide layer. For example, the double layer may have an aluminum oxide layer and a hafnium oxide layer sequentially stacked. The aluminum oxide layer and the hafnium oxide layer may have respective thicknesses of 25 Å and 40 Å when the dielectric material is formed of the double layer. The tantalum oxide layer may have a thickness of 130 Å when the dielectric material is formed of the single layer. The top conductive layer may be double layer-deposited titanium nitride by using a CVD process and a Self-Ionized Plasma Physical Vapor Deposition (SIP-PVD) process. The CVD process and the SIP-PVD process may be performed sequentially. The top conductive layer may be formed of a thickness of about 1,000 Å.

Referring to FIG. 2F, a planarizing insulation layer 150 may be formed to cover the semiconductor substrate 110 having the top electrode 140. The planarizing insulation layer 150 may be formed of silicon oxide deposited by using a CVD process. The planarizing insulation layer 150 may be a TEOS layer deposited by using a PE-CVD process.

Referring to FIG. 2G, the planarizing insulation layer 150 and the interlayer insulation layer 120 may be etched to form a bit line contact hole 151b exposing a desired or predetermined region of the source region 118s, and/or a metal line contact hole 151m exposing a desired or predetermined region of the top electrode 140. The bit line contact hole 151b and/or the metal line contact hole 151m may be filled to form a bit line contact plug 152b and/or a metal line contact plug 152m. For example, the bit line contact plug 152b and/or the metal line contact plug 152m may be formed of tungsten deposited by using a PNL formation process.

Before forming the bit line contact plug 152b and/or the metal line contact plug 152m, a barrier metal layer (not shown) may be formed to reduce diffusion during a thermal treatment process at interface between the bit line contact plug 152b and the metal line contact plug 152m that contact each other, and/or the interlayer insulation layer 120 and the sacrificial insulation layer 126 that contact each other.

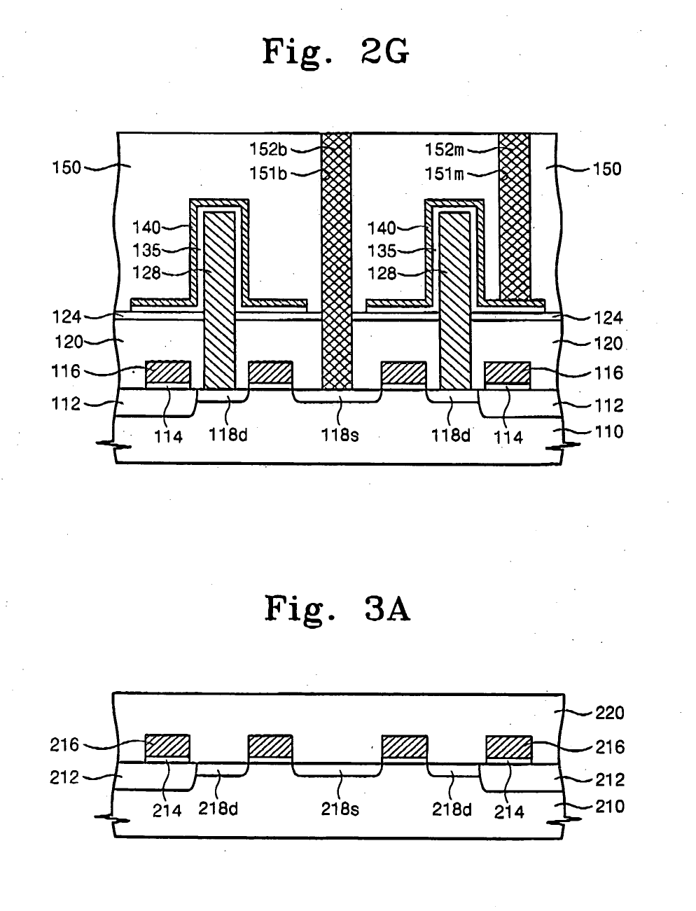

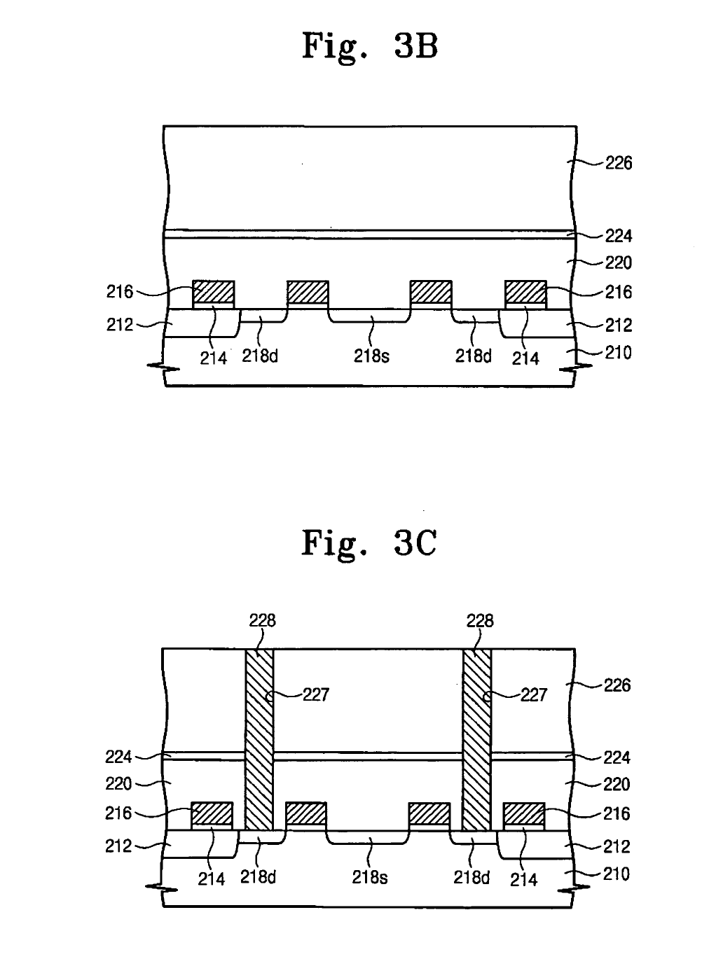

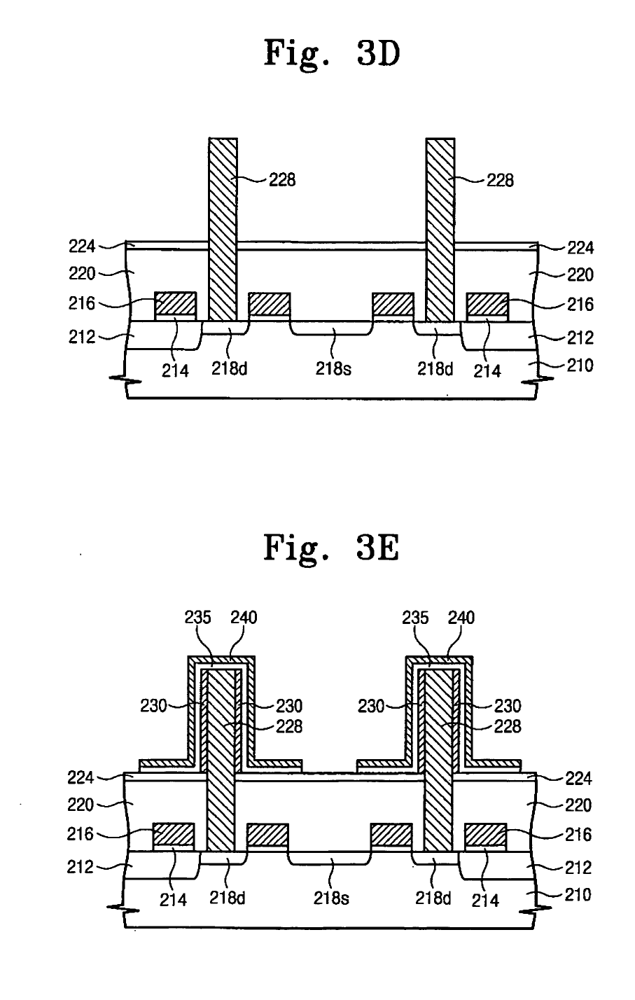

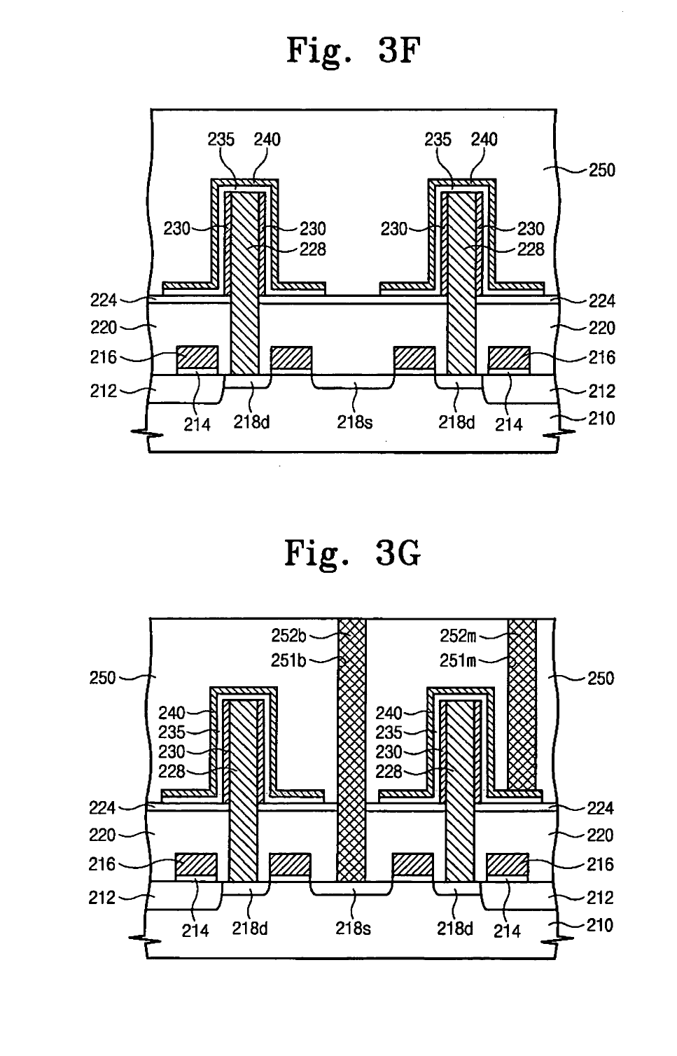

FIGS. 3A to 3G are cross-sectional views illustrating a method for fabricating a capacitor of a semiconductor device according to another example embodiment.

Referring to FIGS. 3A to 3D, processes forming a contact plug 228 that may protrude from an etch stop layer 224 may be identical to that of FIGS. 2A to 2D.

For example, after forming a device isolation layer 212 on a semiconductor substrate 210, a gate oxide layer 214, a gate electrode 216, and/or impurity regions (source/drain regions 218s/218d) may be formed to constitute a MOS transistor.

An interlayer insulation layer 220, an etch stop layer 224, and/or a sacrificial insulation layer 226 may be formed to cover an entire surface of the semiconductor substrate 210 having the MOS transistor. For example, an interlayer insulation layer 220, an etch stop layer 224, and/or a sacrificial insulation layer 226 may be sequentially formed to cover an entire surface of the semiconductor substrate 210 having the MOS transistor. The interlayer insulation layer 226, the etch stop layer 224, and/or the interlayer insulation layer 220 may be etched by using photolithography to form a contact hole 227 exposing a desired or predetermined region of the drain region 218d. The contact plug 228 may be formed to fill the contact hole 227.

Before the forming of the contact plug 228, a barrier metal layer (not shown) may be formed to reduce diffusion at interface between the contact plug 228, the interlayer insulation layer 220, and/or the sacrificial insulation layer 226, which may contact each other.

The sacrificial insulation layer 226 may be removed to expose an upper portion of the contact plug 228 formed on the etch stop layer 224. Accordingly, the contact plug 228 may include a portion that may protrude from the etch stop layer 224.

Referring to FIG. 3E, after depositing a bottom conductive layer along a profile of the etch stop layer 224 including the contact plug 228 that may protrude from the etch stop layer 224, a bottom electrode 230 surrounding the protruding portion of the contact plug 228 may be formed by etching an entire surface. The bottom conductive layer may be formed of titanium nitride deposited by using a CVD process. The bottom conductive layer may have a thickness of about 200 Å.

After depositing a bottom conductive layer, dielectric material, and/or a top conductive layer on the etch stop layer 224 including the protruding portion of the contact plug 228, the bottom electrode 230 may be formed by patterning the result. For example, after sequentially depositing a bottom conductive layer, dielectric material, and/or a top conductive layer on the etch stop layer 224 including the protruding portion of the contact plug 228, the bottom electrode 230 may be formed by patterning the result.

The dielectric material and/or the top conductive layer may be deposited and/or patterned to form the dielectric layer 235 and/or the top electrode 240 on the semiconductor substrate 210 having the bottom electrode 230 that surrounds the protruding portion of the contact plug 228. Accordingly, the capacitor may be formed with the bottom electrode 230 surrounding the protruding portion of the contact plug 228, the dielectric layer 235, and/or the top electrode 240.

The dielectric material may be formed of a double layer having an aluminum oxide layer and a hafnium oxide layer stacked, or a single layer having a tantalum oxide layer. For example, the double layer may have an aluminum oxide layer and a hafnium oxide layer sequentially stacked. The aluminum oxide layer and the hafnium oxide layer may have respective thicknesses of 25 Å and 40 Å when the dielectric material is formed of the double layer. The tantalum oxide layer may have a thickness of 130 Å when the dielectric material is formed of the single layer.

The top conductive layer may be double layer-deposited titanium nitride by using a CVD process and a SIP-PVD process. For example, the CVD process and the SIP-PVD process may be performed sequentially. The top conductive layer may be formed of a thickness of about 1,000 Å.

Referring to FIG. 3F, a planarizing insulation layer 250 may be formed to cover the semiconductor substrate 210 having the top electrode 240. The planarizing insulation layer 250 may be formed of silicon oxide deposited by using a CVD process. The planarizing insulation layer 250 may be a TEOS layer deposited by using a PE-CVD process.

Referring to FIG. 3G, the planarizing insulation layer 250 and/or the interlayer insulation layer 220 may be etched to form a bit line contact hole 251b exposing a desired or predetermined region of the source region 218s, and/or a metal line contact hole 251m exposing a desired or predetermined region of the top electrode 240. The bit line contact hole 251b and/or the metal line contact hole 251m may be filled to form a bit line contact plug 252b and/or a metal line contact plug 252m. For example, the bit line contact plug 252b and/or the metal line contact plug 252m may be formed of tungsten deposited by using a PNL formation process.

Before forming the bit line contact plug 252b and/or the metal line contact plug 252m, a barrier metal layer (not shown) may be formed to reduce diffusion during a thermal treatment process at interface between the bit line contact plug 252b and the metal line contact plug 252m that may contact each other, and/or the interlayer insulation layer 220 and the sacrificial insulation layer 226 that may contact each other.

According to example embodiments, when an outer cylinder capacitor of a semiconductor device having a capacity under bit line structure may be manufactured, manufacturing cost may be reduced and/or processes may be simplified because of processes including use of a mask only once for forming a bit line contact plug and/or excluding a sacrificial material layer for separating a bottom electrode.

Although the semiconductor device may be highly integrated and a design rule may be reduced, an effective coverage may be formed by using the outer cylinder capacity. Accordingly, the void occurrence may be reduced.

Accordingly, when manufacturing a capacitor, there may be provided the capacitor of the semiconductor device of example embodiments reducing manufacturing cost, simplifying processes, and/or achieving stability of a capacitance of the capacitor and/or the semiconductor device, and/or a method for fabricating the same.

Although example embodiments have been shown and described in this specification and figures, it would be appreciated by those skilled in the art that changes may be made to the illustrated and/or described example embodiments without departing from their principles and spirit, the scope of which is defined by the claims and their equivalents.

What is claimed is:

1. A method for fabricating a capacitor of a semiconductor device, the method comprising:
forming an interlayer insulation layer, an etch stop layer, and a sacrificial insulation layer on a semiconductor substrate;
patterning the interlayer insulation layer, the etch stop layer, and the sacrificial insulation layer to form a contact hole exposing a region of the semiconductor substrate;
filling the contact hole to form a contact plug;
removing the sacrificial insulation layer to expose an upper portion of the contact plug, and
forming a dielectric layer and a top electrode on the exposed upper portion of the contact plug.

2. The method of claim 1, wherein each of the interlayer insulation layer and the sacrificial insulation layer is silicon oxide.

3. The method of claim 1, wherein the etch stop layer is one of a silicon oxide nitride layer and a silicon nitride layer.

4. The method of claim 1, wherein the contact plug is tungsten.

5. The method of claim 1, wherein the exposed upper portion of the contact plug is used as a bottom electrode.

6. The method of claim 1, further comprising:
forming an additional bottom electrode on the exposed upper portion of the contact plug.

7. The method of claim 6, wherein forming the additional bottom electrode includes
forming a bottom conductive layer on the exposed upper portion of the contact plug; and
patterning the bottom conductive layer to form the additional bottom electrode on the exposed upper portion of the contact plug.

8. The method of claim 7, wherein the bottom conductive layer is titanium nitride.

9. The method of claim 7, wherein the bottom conductive layer is patterned using an entire surface etching process.

10. The method of claim 1, wherein the dielectric layer is one of a double layer having an aluminum oxide layer and a hafnium oxide layer sequentially stacked, and a tantalum oxide layer.

11. The method of claim 1, wherein the top electrode is titanium nitride.

12. A capacitor of a semiconductor device, the capacitor comprising:
a semiconductor substrate;
an interlayer insulation layer and an etch stop layer covering an entire surface of the semiconductor substrate;
a contact plug protruding from the etch stop layer and connected to a region of the semiconductor substrate; and
a dielectric layer and a top electrode arranged along a profile of the protruding portion of the contact plug and the etch stop layer.

13. The capacitor of claim 12, further comprising:
a gate electrode on the semiconductor substrate, wherein the interlayer insulation layer and the etch stop layer covering the entire surface of the semiconductor substrate cover the gate electrode.

14. The capacitor of claim 12, wherein the interlayer insulation layer is a silicon oxide layer.

15. The capacitor of claim 12, wherein the etch stop layer is one of a silicon oxide nitride layer and a silicon nitride layer.

16. The capacitor of claim 12, wherein the contact plug is tungsten.

17. The capacitor of claim 12, wherein the protruding portion of the contact plug is used as a bottom electrode.

18. The capacitor of claim 12, further comprising:
an additional bottom electrode on the protruding portion of the contact plug.

19. The capacitor of claim 18, wherein the additional bottom electrode is a titanium nitride layer.

20. The capacitor of claim 12, wherein the dielectric layer is one of a double layer having an aluminum oxide layer and a hafnium oxide layer sequentially stacked, and a tantalum oxide layer.

21. The capacitor of claim 12, wherein the top electrode is a titanium nitride layer.
